(19) United States
(12) Patent Application Publication
(10) Pub. No.: US 2023/0275063 A1
(43) Pub. Date: Aug. 31, 2023

(54) 3D-STACKED SEMICONDUCTOR DEVICE WITH IMPROVED ALIGNMENT USING CARRIER WAFER PATTERNING

(71) Applicant: SAMSUNG ELECTRONIC CO., LTD., Suwon-si (KR)

(72) Inventors: Byounghak HONG, Albany, NY (US); Buhyun HAM, Mechanicville, NY (US); Kang-ill SEO, Albany, NY (US); Jason MARTINEAU, Fremont, CA (US)

(73) Assignee: SAMSUNG ELECTRONIC CO., LTD., Suwon-si (KR)

(21) Appl. No.: 17/738,711

(22) Filed: May 6, 2022

Related U.S. Application Data
(60) Provisional application No. 63/314,742, filed on Feb. 28, 2022.

(51) Int. Cl. H01L 23/00

(52) U.S. Cl. CPC H01L 24/80; H01L 24/08; H01L 2224/24145; H01L 2224/80143; H01L 2224/80895; H01L 2224/80896; H01L 2924/3511

(57) ABSTRACT

Provided is a semiconductor device that includes: a 1^{st} carrier wafer; and a 1^{st} semiconductor chip on the 1^{st} carrier wafer, wherein the 1^{st} carrier wafer includes at least one 1^{st} pattern, and the 1^{st}pattern includes therein a 1^{st} stress material which is different from a material forming the 1^{st} carrier wafer, and configured to expand or shrink by thermal processing.

### CROSS-REFERENCE TO RELATED APPLICATION

This application is based on and claims priority from U.S. Provisional Application No. 63/314,742 filed on Feb. 28, 2022 in the U.S. Patent and Trademark Office, the disclosure of which is incorporated herein in its entirety by reference.

### BACKGROUND

### 1. Field

Apparatuses and methods consistent with example embodiments of the disclosure relate to a semiconductor device formed using a carrier wafer, and more particularly, to a three-dimensional (3D) semiconductor device formed by bonding semiconductor chips using a carrier wafer having a patterned surface.

### 2. Description of the Related Art

As the requirements for semiconductor device density and smaller packaging increase, three-dimensional (3D) integration of semiconductor chips or devices has been introduced. A 3D-stacked semiconductor device may be obtained by stacking and bonding two or more semiconductor chips or devices to each other in a vertical direction. For this process, a semiconductor chip may be attached to a carrier wafer and aligned with another semiconductor chip on another carrier wafer, and the two semiconductor chips may be vertically bonded together through a thermal process on a bonding chuck. The term “carrier wafer” may also refer to “handler wafer” or “carrier substrate.”

However, during the manufacturing process including deposition, patterning and etching, etc. along with thermal treatment, each of the semiconductor chips to be bonded to each other may have undergone horizontal distortion such as bending or warpage, and thus, their bonding surfaces such as a back-end-of-line (BEOL) layer including metal lines insulated by an interlayer dielectric (ILD) material may be bent or warped. Thus, bonding two semiconductor devices at their horizontally distorted BEOL layer surfaces is a challenge in manufacturing a 3D-stacked semiconductor device.

FIG. 1A illustrates two semiconductor chips vertically facing to be bonded to each other, and FIGS. 1B and 1C illustrates respective 3D-stacked semiconductor devices in which the two semiconductor chips in FIG. 1A are vertically bonded, according to a related art.

Referring to FIG. 1A, a 1^{st} semiconductor chip 10A at a lower stack includes a substrate 110, a front-end-of-line (FEOL) layer 111, a middle-of-line (MOL) layer 112 and a back-end-of-line (BEOL) layer 113, in this order, on a 1^{st} surface 1S of a carrier wafer 101. FIG. 1A also shows that a 2^{nd} semiconductor chip 10B at an upper stack includes a substrate 120, an FEOL layer 121, an MOL layer 122 and a BEOL layer 123, in this order, on a 1^{st} surface 1S a carrier wafer 102.

In FIG. 1A, the 2^{nd} semiconductor chip 10B is in an upside-down state such that the BEOL layer 123 thereof faces the BEOL layer 113 of the 1^{st} semiconductor chip 10A before the two semiconductor chips 10A and 10B are vertically bonded to each other.

The FEOL layer (or device layer) may refer to a layer in which primary structures of a semiconductor device such as transistor is formed. For example, a substrate or device substrate, a channel structure (fins of a fin-field effect transistor (FinFET) or nanosheet layers of a nanosheet transistor), source/drain regions, a gate electrode, etc. may be formed in the FEOL layer. In the MOL layer (or contact layer), contact structures such as a source/drain contact plug, a gate contact plug and corresponding vias may be formed. The BEOL layer (or interconnect layer) may refer to a layer in which interconnect elements such as metal lines connected to a voltage source or used for signal routing from/to another circuit element may be formed. Herein, the FEOL layer, the MOL layer and the BEOL layer may also refer to elements or structures included in the respective layers.

It is noted in FIG. 1A that a 1^{st} surface 1S of the BEOL layer 113 of the 1^{st} semiconductor chip 10A is bent convex in an upward direction, and a 1^{st} surface 15 of the opposing BEOL layer 123 of the 2^{nd} semiconductor chip 10B is bent convex in a downward direction. This surface bending of the BEOL layers 113 and 123 may have occurred through various operations in their manufacturing process.

The 1^{st} surfaces 1S of the BEOL layers 113 and 123 may be surfaces of ILD structures 113-1 and 123-1 that insulate metal lines 113-2 and 123-2 for the respective semiconductor chips 10A and 10B. Surfaces of the metal lines 113-2 and 123-2 may also form the 1^{st} surfaces 1S of the BEOL layers 113 and 123, respectively. Thus, in FIG. 1A, the surfaces of the ILD structures 113-1 and 123-1 and/or the surfaces of the metal lines 113-2 and 123-2 may be bent convex or warped. The ILD structures 113-1 and 123-1 may be formed of, for example, low-k materials such as silicon dioxide (SiO₂) or silicon oxynitride (SiON), not being limited thereto, and the metal lines 113-2 may be formed of at least one of copper (Cu), titanium (Ti), tantalum (Ta), aluminum (Al), tungsten (W), cobalt (Co), molybdenum (Mo), ruthenium (Ru), etc.

When the two semiconductor chips 10A and 10B are vertically mirror-bonded at the bent-convex 1^{st} surfaces 1S of their BEOL layers 113 and 123 to form a 3D-stacked semiconductor device 10, damaging misalignment or disconnection causing resistance-capacitance (RC) delays may occur therebetween, as shown in FIG. 1B. Further, when the bonding 1^{st} surfaces 1S of the BEOL layers 113 and 123 are annealed, an undesired severe warpage or distortion may occur therebetween in the 3D-stacked semiconductor device 10 as shown in FIG. 1C.

Similar misalignment or warpage problems may arise when a 3D-stacked semiconductor device is formed by vertically bonding two semiconductor chips with backside power delivery network (BSPDN) structures.

FIGS. 2A and 2B illustrates a 3D-stacked semiconductor device in which two semiconductor chips with BSPDN structures are vertically bonded to each other to form the 3D-stacked semiconductor device, according to a related art.

Referring to FIGS. 2A and 2B, a 3D-stacked semiconductor device 20 is formed by vertically bonding a 1^{st} semiconductor chip 20A at a lower stack to a 2^{nd} semiconductor chip 20B at an upper stack. The 1semiconductor chip 20A includes a BEOL layer 211, an MOL layer 212, an FEOL layer 213 and a BSPDN layer 214, in this order, on a 1^{st} surface 1S of a carrier wafer 201, and the 2^{nd} semiconductor chip 20B includes an ILD layer 220, a BEOL layer 221, an MOL layer 222, an FEOL layer 223 and a BSPDN layer 224, in this order, on a 1^{st} surface 1S of a carrier wafer 202.

Here, the BEOL layers 211 and 221 may include ILD structures 211-1 and 221-1 and metal lines 211-2 and 221-2 respectively insulated by the ILD structures 211-1 and 221-1. Materials forming the ILD structures 211-1 and 221-1 and the metal lines may 211-2 and 221-2 may be the same or similar to those forming the ILD structures 111-1 and 121-1 and metal lines may 111-2 and 121-2 of a 3D-stacked semiconductor device 10 in FIGS. 1B and 1C, respectively. The BSPDN layers 214 and 224 may refer to backside layers in which other ILD structure 214-1 and 224-1 respectively insulate BSPDN structures 214-2 and 224-2 that deliver power voltages to the respective semiconductor chip 20A and 20B.

Unlike the two semiconductor chips 10A and 10B shown in FIGS. 1B and 1C, the two semiconductor chips 20A and 20B are vertically bonded to each other at 1^{st} surfaces 1S of the BSPDN layers 214 and 214. However, similar to the two semiconductor chips 10A and 10B shown in FIGS. 1A to 1C, each of the boning 1^{st} surfaces 1S of the BSPDN layers 214 and 224 may also be bent convex. That is, the surfaces of the other ILD structures 214-1 and 224-1 and/or the surfaces of the BSPDN structures 214-2 and 224-2 may be bent convex or warped. Thus, the 3D-stacked semiconductor device 20 formed by mirror-bonding the two semiconductor chips 20A and 20B at their BSPDN layers 214 and 224 may also have a misaligned, disconnected or severely warped boning surface as shown in FIGS. 2A and 2B, respectively.

The above phenomena of misalignment, disconnection or warpage may also occur when the bonding surfaces 1S of the semiconductor chips 10A, 10B, 20A and 20B are bent to be concave or take differently bent- or warped-shapes during the manufacturing process. The same or similar phenomena may occur when differently-structured semiconductor chips that may have undergone different manufacturing processes are bonded to each other to form a 3D-stacked semiconductor device. Thus, 3D-stacked semiconductor devices formed by bonding their bent or warped surfaces as described above may have unexpectedly degraded performance.

Therefore, there is demand of an improved bonding scheme for a 3D-stacked semiconductor device that may address the above problems.

Information disclosed in this Background section has already been known to the inventors before achieving the embodiments of the present application or is technical information acquired in the process of achieving the embodiments described herein. Therefore, it may contain information that does not form prior art that is already known to the public.

### SUMMARY

The disclosure provides a carrier wafer on which a semiconductor chip is attached to. The carrier wafer may include a plurality of patterns in which one or more stress materials may be filled in to expand and shrink the carrier wafer when the semiconductor chip is thermally processed to be bonded to another semiconductor chip.

The disclosure also provides a semiconductor device formed by two semiconductor chips to each other using respective carrier wafers each of which is patterned to include one or more stress materials.

According to embodiments, there is provided a semiconductor device that may include: a 1^{st} carrier wafer; and a 1^{st} semiconductor chip on the 1^{st} carrier wafer, wherein the 1^{st} carrier wafer includes at least one 1^{st} pattern, and the at least one 1^{st} pattern may include therein a 1^{st} stress material which is different from a material forming the 1^{st} carrier wafer, and configured to expand or shrink by thermal processing. The semiconductor device may further include a 2^{nd} semiconductor chip vertically bonded to the 1^{st} semiconductor chip. The 2^{nd} semiconductor chip may be on a 2^{nd} carrier wafer that may include at least one 2^{nd} pattern, and the at least one 2^{nd} pattern may include a 2^{nd} stress material which is different from a material forming the 2^{nd} carrier wafer, and configured to expand or shrink by the thermal processing.

According to embodiments, there is provided a carrier wafer that may include: a 1^{st} surface on which an integrated circuit is to be attached; and a 2^{nd} surface opposite to the 1^{st} surface, wherein at least one pattern is formed on the 2^{nd} surface, and a stress material is included in the at least one pattern, and wherein the stress material is different from a material forming the carrier wafer, and configured to expand or shrink subject to thermal processing.

According to embodiments, there is provided a method of manufacturing a semiconductor device, that may include: providing a 1^{st} semiconductor chip and a 2^{nd} semiconductor chip; determining characteristics of a 1^{st} bonding surface of the 1^{st} semiconductor chip and a 2^{nd} bonding surface of the 2^{nd} semiconductor chip to be bonded to the 1^{st} bonding surface; forming the 1^{st} semiconductor chip on a 1^{st} carrier wafer, and forming a 2^{nd} semiconductor chip on a 2^{nd} carrier wafer; and vertically bonding the 1^{st} semiconductor chip and the 2^{nd} semiconductor chip to each other through a thermal process, wherein at least one of the 1^{st} carrier wafer and the 2^{nd} carrier wafer includes a plurality patterns and a stress material therein which is different from a material forming the 1^{st} carrier wafer or the 2^{nd} carrier wafer, and configured to expand or shrink by the thermal process.

### BRIEF DESCRIPTION OF DRAWINGS

Example embodiments of the disclosure will be more clearly understood from the following detailed description taken in conjunction with the accompanying drawings in which:

FIG. 1A illustrates two semiconductor chips vertically facing to be bonded to each other, and FIGS. 1B and 1C illustrates respective 3D-stacked semiconductor devices in which the two semiconductor chips in FIG. 1A are vertically bonded, according to a related art;

FIGS. 2A and 2B illustrates a 3D-stacked semiconductor device in which two semiconductor chips with BSPDN structures are vertically bonded to each other to form the 3D-stacked semiconductor device, according to a related art;

FIG. 3 illustrates a 3D-stacked semiconductor device in which two semiconductor chips are vertically bonded, according to an embodiment;

FIG. 4 illustrates a 3D-stacked semiconductor device in which two semiconductor chips are vertically bonded, according to another embodiment;

FIG. 5 illustrates a 3D-stacked semiconductor device in which two semiconductor chips with backside power delivery network (BSPDN) structures are vertically bonded, according to an embodiment;

FIGS. 6A to 6D illustrate a plurality of different patterns for a carrier wafer, according to embodiments;

FIG. 7 illustrates a method for manufacturing a 3D-stacked semiconductor device by controlling bending or warpage on a bonding surface of at least one semiconductor chip, according to embodiments; and

FIG. 8 is a schematic block diagram illustrating an electronic device including a 3D-stacked semiconductor device formed by vertically bonding two semiconductor chips as shown in FIGS. 3 to 5, according to an example embodiment.

### DETAILED DESCRIPTION OF EMBODIMENTS

The embodiments described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, a material or materials forming a metal line, a via or super via may not be limited to metals of which examples are taken herein as long as the disclosure can be applied thereto. Further, the use of the super via scheme described herein may not be limited to the BEOL of a semiconductor device, and instead, may be applied to a different structure or device.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “upper,” “lower,” “top,” “bottom,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is flipped upside town or turned over, elements described as “below” or “beneath” other elements would then be oriented “above” the other elements, and a “top” or “upper” surface of an element would be a “bottom” or “lower” surface of the element. Thus, for example, the term “below” can encompass both an orientation of above and below, and the term “top” can encompass both a position of top and bottom, subject to the corresponding situation. The semiconductor device may be otherwise oriented (rotated 90 degrees or at other orientations) and the spatially relative descriptors used herein interpreted accordingly.

As used herein, expressions such as “at least one of,” when preceding a list of elements, modify the entire list of elements and do not modify the individual elements of the list. For example, the expression, “at least one of a, b, and c” should be understood as including only a, only b, only c, both a and b, both a and c, both b and c, or all of a, b, and c.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional illustrations that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept. Further, in the drawings, the sizes and relative sizes of layers and regions may be exaggerated for clarity.

For the sake of brevity, some conventional elements of a semiconductor device or processes required for manufacturing the semiconductor device may or may not be described in detail herein or shown in the drawings. For example, a shallow trench isolation (STI) structure insulating an active region of a transistor from another circuit element in a semiconductor device may not be described or shown. An adhesive layer formed in a bonding surface may also not be described or shown. Further, details of conventional lithographing, masking, etching, deposition and annealing processes used in manufacturing a semiconductor device may or may not be described or shown.

In order to address the problems of distortion in a semiconductor chip and misalignment and warpage between bonding surfaces of two or more semiconductor chips, various embodiments of applying patterns to a surface of a carrier wafer are provided herebelow.

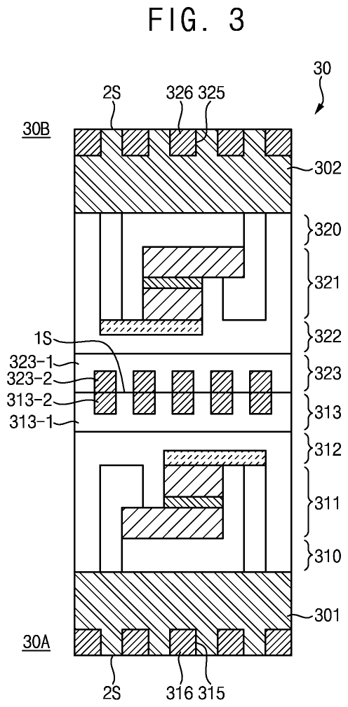

FIG. 3 illustrates a 3D-stacked semiconductor device in which two semiconductor chips are vertically bonded, according to an embodiment.

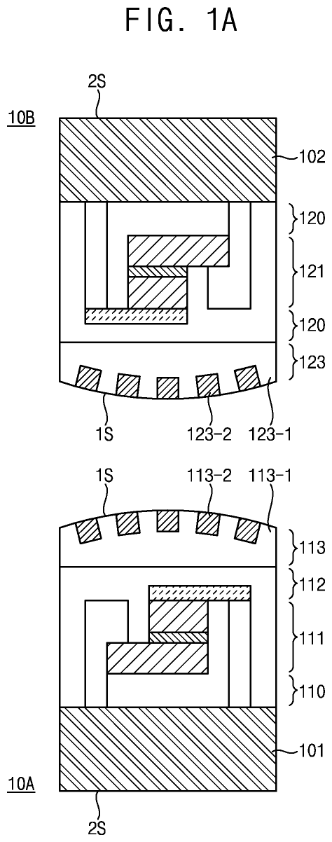

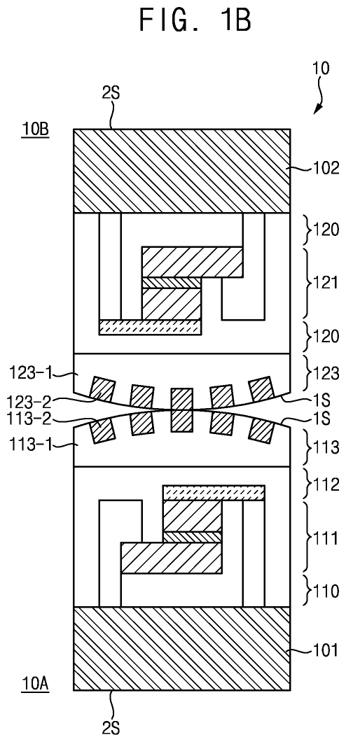

Referring to FIG. 3, a 3D-stacked semiconductor device 30 may be formed by vertically bonding a 1^{st} semiconductor chip 30A at a lower stack with a 2^{nd} semiconductor chip 30B at an upper stack. Like the two semiconductor chips 10A and 10B shown in FIGS. 1A to 1C, a 1^{st} semiconductor chip 30A may include a substrate 310, an FEOL layer 311, an MOL layer 312 and a BEOL layer 313, in this order, on a 1^{st} surface 1S of a carrier wafer 301, and a 2^{nd} semiconductor chip 30B may include a substrate 320, an FEOL layer 321, an MOL layer 322 and a BEOL layer 323, in this order, on a 1^{st} surface of a carrier wafer 302.

Also, like the two semiconductor chips 10A and 10B, the two semiconductor chips 30A and 30B may be bonded to each other at their BEOL layers 313 and 323 facing each other. The BEOL layers 313 and 323 may include ILD structures 313-1 and 323-1 and metal lines 313-2 and 323-2 respectively insulated by the ILD structures 313-1 and 323-1. Thus, bonding surfaces 1S of the BEOL layers 313 and 323 may include the surfaces of the ILD structures 313-1 and 323-1 and the surfaces of the metal lines 313-2 and 323-2. Materials forming the ILD structures 313-1 and 323-1 and the metal lines 313-2 and 323-2 may be the same or similar to those of the ILD structures 113-1 and 123-1 and the metal lines 113-2 and 123-2 described in reference to FIGS. 1A to 1C, and thus, duplicate descriptions are omitted herebelow.

However, the semiconductor chips 30A and 30B may be different from the semiconductor chips 10A and 10B shown in FIGS. 1A to 1C by a structure of their carrier wafers 301 and 302 and a shape of the bonding surfaces 1S of the BEOL layers 313 and 323.

According to an embodiment, the carrier wafer 301 of the 1^{st} semiconductor chip 30A may have a patterned 2^{nd} surface 2S (bottom surface) as shown in FIG. 3, while the respective carrier wafers 101 and 102 of the two semiconductor chips 10A and 10B shown in FIGS. 1A to 1C have plain 2^{nd} surfaces 2S. Further, according to an embodiment, a plurality of patterns 315 formed on the 2^{nd} surface 2S of the carrier wafer 301 may be filled in with one or more materials 316 selected based on thermal expansion coefficients of the materials 316. Herein, the term “pattern(s)” may refer to hole(s), recess(es), trench(es) or indentation.

Here, the patterns 315 on the 2^{nd} surface 2S of the carrier wafer 301 may be formed by, for example, etching a plain surface to form a plurality of trenches, recesses or holes, according to an embodiment. The materials 316 filled in the patterns 315 on the 2^{nd} surface 2S of the carrier wafer 301 may include a tensile stress material such as silicon germanium (SiGe), according to an embodiment. It is known that tensile stress materials have expansion tendency with a thermal expansion coefficient greater than that of silicon (Si) forming the carrier wafer 301. Thus, if a 1^{st} surface 1S of the BEOL layer 313 of the 1^{st} semiconductor chip 30A is bent convex to an upward direction like the BEOL layer 113 of the 1^{st} semiconductor chip 10A shown in FIG. 1A, it may be controlled to be flat by the expansion of the tensile stress material in the patterns 315 on the 2^{nd} surface 2S of the carrier wafer 301, when the two semiconductor chips 30A and 30B are vertically bonded to each other at their BEOL layers 313 and 323 through thermal processing, as shown in FIG. 3.

According to another embodiment, the materials 316 filled in the patterns 315 on the 2^{nd} surface 2S of the carrier wafer 301 may include a compressive stress material such as silicon carbide (SiC). It is known that compressive stress materials have expansion tendency with a thermal expansion coefficient smaller than that of Si forming the carrier wafer 301. Thus, if the 1^{st} surface 1S of the BEOL layer 313 of the 1^{st} semiconductor chip 30A is bent concave to the upward direction, it may be controlled to be flat by shrinkage of the compressive stress material in the patterns 315 on the 2^{nd} surface 2S of the carrier wafer 301, when the two semiconductor chips 30A and 30B are vertically bonded to each other at their BEOL layers 313 and 323 through thermal processing, as shown in FIG. 3.

In the meantime, the carrier wafer 302 of the 2^{nd} semiconductor chip 30B may also have a plurality patterns 325 on a 2^{nd} surface 2S (top surface), and one or more materials 326 selected based on thermal expansion coefficients may be filled in the patterns 325, according to an embodiment. Thus, when the 1^{st} surface 1S of the BEOL layer 313 of the 1^{st} semiconductor chip 30A is controlled as described above, a 1^{st} surface 1S of the BEOL layer 323 of the 2^{nd} semiconductor chip 30B may be controlled by the patterns 325 of the carrier wafer 302 of the 2^{nd} semiconductor chip 30B and the materials 326 filled therein in the same or similar manner, according to embodiments.

The materials 326 filled in the patterns 325 on the 2^{nd} surface 2S of the carrier wafer 302 may also include a tensile stress material such as SiGe. Accordingly, if a 1^{st} surface 1S of the BEOL layer 323 of the 2^{nd} semiconductor chip 30B is bent convex to a downward direction like the BEOL layer 123 of the 2^{nd} semiconductor chip 10B shown in FIG. 1A, it may be controlled to be flat by the expansion of the tensile stress material in the patterns 325 on the 2^{nd} surface 2S of the carrier wafer 302, when the two semiconductor chips 30A and 30B are vertically bonded to each other, as shown in FIG. 3.

Similarly, the materials 326 filled in the patterns 325 on the 2^{nd} surface 2S of the carrier wafer 302 may also include a compressive stress material such as SiC. Accordingly, if the 1^{st} surface 1S of the BEOL layer 323 of the 2nd semiconductor chip 30B is bent concave to the downward direction, it may be controlled to be flat by shrinkage of the compressive stress material in the patterns 325 on the 2^{nd} surface 2S of the carrier wafer 302, when the two semiconductor chips 30A and 30B are vertically bonded to each other, as shown in FIG. 3.

In the above embodiments, both of the 1^{st} surfaces 1S of BEOL elements 313 and 323 of the two semiconductor chips 30A and 30B are controlled to be flat by the respective 2^{nd} surfaces 2S of the carrier wafers 301 and 302. However, the disclosure is not limited thereto.

According to embodiments, the 1^{st} surface 1S of only one of the BEOL layers 313 and 323 may be controlled to be flat by patterning the 2^{nd} surface 2S of only one of the carrier wafers 301 and 302. This patterning scheme may be considered when the 1^{st} surface 1S of the other of the BEOL layers 313 and 323 is not bent or warped, and thus, a bonding surface control is not necessary for the other of the BEOL layers 313 and 323.

According to embodiments, when the 1^{st} surface 1S of the BEOL layer 313 is bent concave (or convex), the 1^{st} surface 1S of the BEOL layer 323 may be controlled to be bent convex (concave) while the 1^{st} surface 1s of the BEOL layer 313 remains bent concave (convex) without being controlled. Thus, the bonding two 1^{st} surfaces 1S can be conformally bonded when the two semiconductor chips 30A and 30B are vertically bonded.

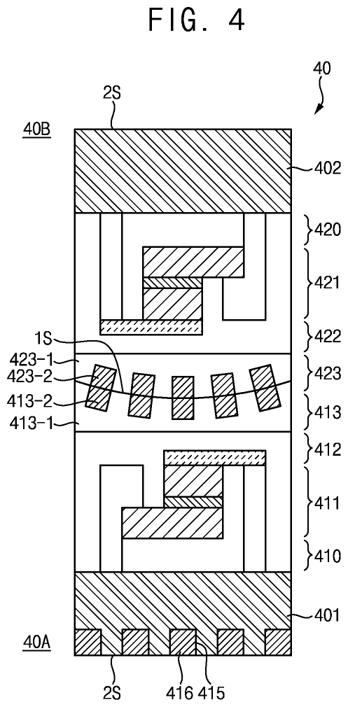

FIG. 4 illustrates a 3D-stacked semiconductor device in which two semiconductor chips are vertically bonded, according to another embodiment.

Referring to FIG. 4, a 3D-stacked semiconductor device 40 may be formed by vertically bonding a 1^{st} semiconductor chip 40A at a lower stack with a 2^{nd} semiconductor chip 40B at an upper stack. Similar to the two semiconductor chips 30A and 30B of the 3D-stacked semiconductor device 30 in FIG. 3, the 1^{st} semiconductor chip 40A may include a substrate 410, an FEOL layer 411, an MOL layer 412 and a BEOL layer 413, in this order, on a 1^{st} surface 1S of a carrier wafer 401, and the 2^{nd} semiconductor chip 40B may include a substrate 420, an FEOL layer 421, an MOL layer 422 and a BEOL layer 423, in this order, on a 1^{st} surface of a carrier wafer 402.

Like the two semiconductor chips 30A and 30B, the two semiconductor chips 40A and 40B may be bonded at their BEOL layers 413 and 423 facing each other. The BEOL layers 413 and 423 may include ILD structures 413-1 and 423-1 and metal lines 413-2 and 423-2 respectively insulated by the ILD structures 413-1 and 423-1. Thus, bonding surfaces 15 of the BEOL layers 413 and 423 may include the surfaces of the ILD structures 413-1 and 423-1 and the surfaces of the metal lines 413-2 and 423-2. Materials forming the ILD structures 413-1 and 423-1 and the metal lines 413-2 and 423-2 may be the same or similar to those of the ILD structures 113-1 and 123-1 and the metal lines 113-2 and 123-2 described in reference to FIGS. 1A to 1C, and thus, duplicate descriptions are omitted herebelow.

The carrier wafer 401 of the 1^{st} semiconductor chip 40a may have a plurality of patterns on its 2^{nd} surface 2S with stress materials (e.g., compressive or tensile stress materials) filled therein as the carrier wafer 301 of the 1^{st} semiconductor chip 30A. In contrast, the carrier wafers 402 of the 2^{nd} semiconductor chip 40B may have a plain 2^{nd} surface 2S without any patterns and stress materials therein. Thus, a 1^{st} surface 1S of the BEOL layer 423 of the 2^{nd} semiconductor chip 40B on the upper stack may not have been controlled by the carrier wafer 402 to be flat, and instead, may remain bent to be convex to the downward direction. In this case, in order to avoid misalignment, disconnection or warpage when the two semiconductor chips 40A and 40B are bonded, a 1^{st} surface 1S of the BEOL layer 413 may be controlled to be bent concave to the upward direction so that the concave surface may be conformally bonded to the convex surface as shown in FIG. 4, according to an embodiment. As described above, the concave 1^{st} surface IS of the BEOL layer 413 may be obtained by filling one or more compressive stress materials in the patterns on the 2^{nd} surface of the carrier wafer 401 of the 1^{st} semiconductor chip 40A.

In a similar manner, when the 1^{st} surface 1S of the BEOL layer 423 of the 2^{nd} semiconductor chip 40B is bent concave to the downward direction, the bonding 1^{st} surface 1S of the BEOL layer 413 of the 1^{st} semiconductor chip 40A may be controlled to be bent convex to the upward direction for conformal bonding, according to an embodiment. As described above, the convex 1^{st} surface 1S of the BEOL layer 413 may be obtained by filling one or more tensile stress materials in the patterns on the 2^{nd} surface of the carrier wafer 401 of the 1^{st} semiconductor chip 40A.

Patterning a carrier wafer and filling in stress materials therein to control at least one bonding surface between two semiconductor chips may also apply to bonding two semiconductor chips with respective backside power delivery network (BSPDN) structures.

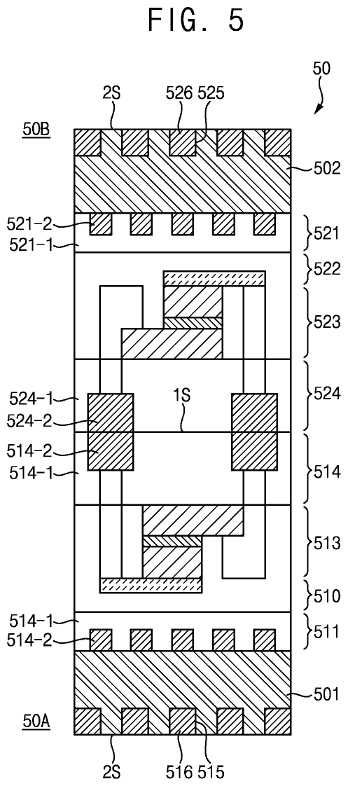

FIG. 5 illustrates a 3D-stacked semiconductor device in which two semiconductor chips with BSPDN structures are vertically bonded, according to an embodiment.

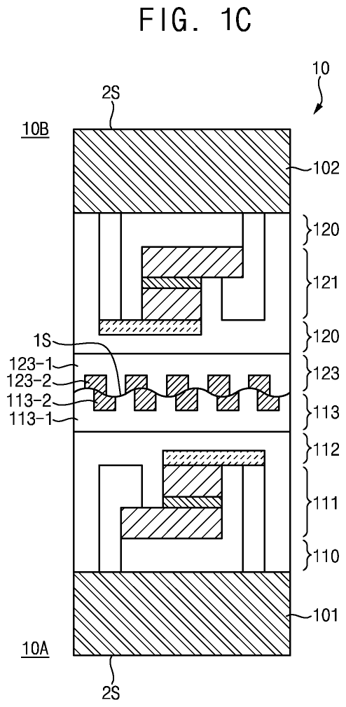

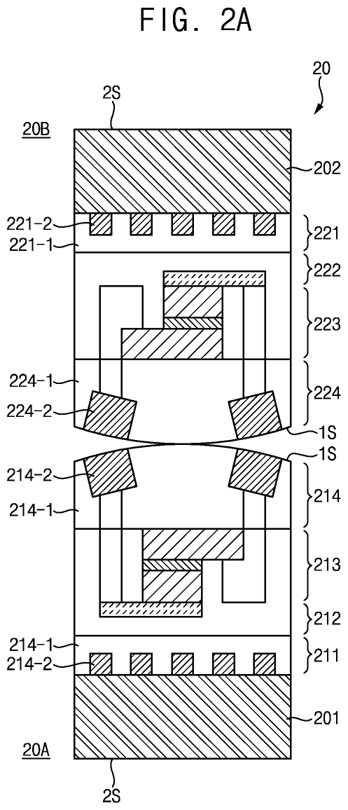

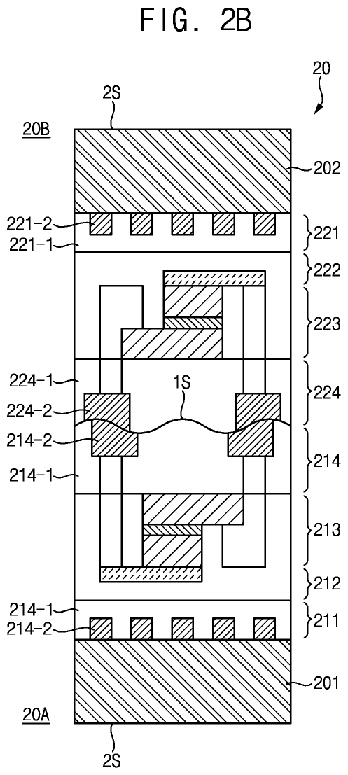

Referring to FIG. 5, a 3D-stacked semiconductor device 50 may be formed by vertically bonding a 1^{st} semiconductor chip 50A at a lower stack with a 2^{nd} semiconductor chip 50B at an upper stack. Like the semiconductor chips 20A and 20B shown in FIGS. 2A and 2B, the 1^{st} semiconductor chip 50A may include a BEOL layer 511, an MOL layer 512, an FEOL layer 513 and a BSPDN layer 514, in this order, on a 1^{st} surface IS of a carrier wafer 501, and a 2^{nd} semiconductor chip 50B may include a BEOL layer 521, an MOL layer 522, an FEOL layer 523 and a BSPDN layer 524, in this order, on a 1^{st} surface IS of a carrier wafer 202.

The BEOL layers 511 and 521 may include ILD structures 511-1 and 521-1 and metal lines 511-2 and 521-2 respectively insulated by the ILD structures 511-1 and 521-1. Materials forming the ILD structures 511-1 and 521-1 and the metal lines may 511-2 and 521-2 may be the same or similar to those forming the ILD structures 111-1 and 121-1 and metal lines may 111-2 and 121-2 of the 3D-stacked semiconductor device 10 in FIGS. 1A to 1C. Thus, duplicate descriptions are omitted herebelow.

Like the two semiconductor chips 20A and 20B, the two semiconductor chips 50A and 50B may be bonded at their BSPDN layers 514 and 524 facing each other. The BSPDN layers 514 and 524 may refer to backside layers in which other ILD structure 514-1 and 524-1 respectively insulate BSPDN structures 514-2 and 524-2 that deliver power voltages to the respective semiconductor chip 50A and 50B. Thus, 1st surfaces 1S of the BSPDN layers 514 and 524, which are bonding surfaces, may include surfaces of the other ILD structures 514-1 and 524-1 and surfaces of the BSPDN structures 514-2 and 524-2.

Similar to the carrier wafers 301 and 302 of the two semiconductor chips 30A and 30B, the carrier wafers 501 and 502 may also have a plurality of patterns 515 and 525 on 2^{nd} surfaces thereof, respectively, according to an embodiment. Further, one or more stress materials 516 and 526 may be filled in these patterns 515 and 525 of the carrier wafers 501 and 502, respectively, according to an embodiment.

Thus, when the two semiconductor chips 50A and 50B are vertically bonded to each other at their BSPDN layers 514 and 524, the boning 1^{st} surfaces 1S of the BSPDN layers 514 and 524 may be controlled to be flat by the patterns 515 and 525 and the stress materials 516 and 526 filled therein, according to an embodiment. As described in reference to FIG. 3, the stress materials 515 and 525 may include a tensile stress material which controls bent convex 2^{nd} surfaces of the BSPDN layers 514 and 524 to be flat or a compressive stress material which controls bent concave 2^{nd} surfaces of the BSPDN layers 514 and 524 to be flat.

Similar to the embodiment described in reference to FIG. 4, the bonding 2^{nd} surface 2S of the BSPDN layer 514 of the 1^{st} semiconductor chip 50A may be controlled to be bent concave or bent convex to the upward direction when the bonding 2^{nd} surface 2S of the BSPDN layer 524 of the 2^{nd} semiconductor chip 50B is bent convex or bent concave to the downward direction, according to embodiments.

In the above embodiments, it may be possible to change shapes of bonding surfaces of BEOL layers or BSPDN layers of two semiconductor chips by controlling expansion or shrinkage of carrier wafers to which the two semiconductor chips are attached, respectively. These embodiments may be enabled at least because a thickness of each of the semiconductor chips described above is in a nanometer scale, for example, in a range of 200 nm to 300 nm, and thus, the effect of thermal expansion of shrinkage at one side of each of the semiconductor chips may be transferred to an opposite side of each of the semiconductor chips.

In the above embodiments, patterns are formed on a bottom surface of a carrier wafer (e.g., the 2^{nd} surface 2S of the carrier wafer 301), opposite to an upper surface (e.g., the 1^{st} surface 1S of the carrier wafer 301) on which a semiconductor chip is attached. However, these patterns may be formed in other areas of the carrier wafer, and a compressive or tensile stress material may be filled therein as long as the carrier wafer may be able to control a bonding surface of a semiconductor chip when this semiconductor chip is bonded to another semiconductor chip though thermal processing, according to embodiments. For example, the material may be filled in patterns formed inside the carrier wafer. Further, a pattern and a material in a carrier wafer of a lower-stack semiconductor chip may not be the same as a pattern and a material in a carrier wafer of an upper-stack semiconductor chip to control bonding surfaces of the two semiconductor chips, according to embodiments.

Due to the above embodiments, a 3D-stacked semiconductor device formed by vertically bonding two semiconductor chips may avoid misalignment, disconnection or warpage at their bonding surfaces of BEOL layers or BSPDN layers.

In the above embodiments, a bonding surface of a semiconductor chip to be controlled by patterns and materials of a carrier wafer includes a surface of a BEOL layer or a BSPDN layer. However, the disclosure is not limited thereto, and thus, the bonding surface of a semiconductor chip to be controlled by the patterns and materials of the carrier wafer may be a different layer, e.g., an MOL layer or an FEOL layer.

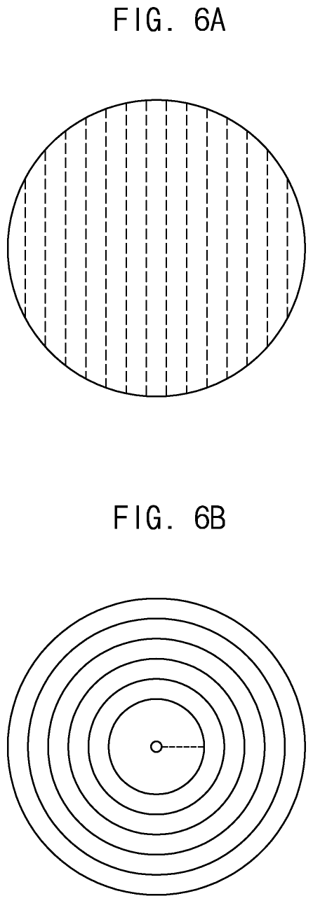

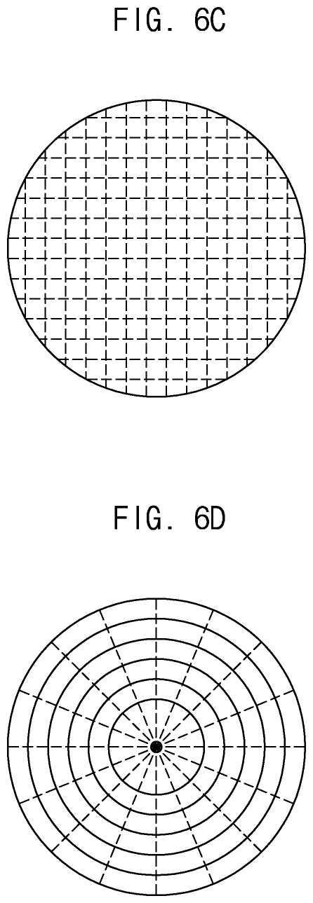

In the meantime, a bent or warped bonding surface of a semiconductor chip to be controlled by a bottom surface of a carrier wafer may take various different shapes or forms, not being limited to the vertically convex or concave shape in the above embodiments. Thus, subject to the shapes or forms of a bonding surface, a bottom surface of a carrier wafer to control the bonding surface may also take various different shapes or forms as shown in FIGS. 6A to 6D, according to embodiments.

FIG. 6A illustrates a plurality of stipe patterns for a carrier wafer, FIG. 6B illustrates a plurality of concentric circle patterns for a carrier wafer, FIG. 6C illustrates a plurality of grid patterns for a carrier wafer, and FIG. 6D illustrates a plurality of polar grid patterns for a carrier wafer. However, the patterns of the carrier wafers 301, 302, 401, 402, 501 and 502 in the above embodiments are not limited to these examples. For example, although the patterns of the carrier wafers shown in FIGS. 6A to 6D have constant intervals therebetween in various directions, the intervals may not be constant subject to the bonding surface to be controlled. As another example, although each of the carrier wafers 301, 302, 401, 402, 501 and 502 has a plurality of patterns on its second surface 2S, only one pattern may be formed to contain stress a material therein to control a corresponding bonding surface.

According to an embodiment, a pool of carrier wafers having various different patterns on their bottom surfaces with a plurality of stress materials filled therein is prepared. Thus, when characteristics of distortion of a bonding surface of a semiconductor chip to be bonded to another semiconductor chip are determined and identified, a carrier wafer having corresponding patterns and material(s) filled therein that may counter act the characteristics of the distortion may be selected from the pool of carrier wafers. The carrier wafer pool may also include a carrier wafer that does not have a pattern on its bottom surface like the carrier wafers 101 and 201 shown in FIGS. 1A to 1C.

The characteristics of the bonding surface may include types of the bonding surface, existence of distortion of the bonding surface, a type, dimensions such as a curvature value, a position, etc. of the distortion on the bonding surface, a distorted material in the bonding surface, etc., according to embodiments. Here, the type of the bonding surface may include a BEOL layer, a BSPDN layer, etc., not being limited thereto. Further, the carrier wafers included in the pool may be prepared to counter act these characteristics of the distortion of the bonding surface through various experiments and empirical results.

In the meantime, the characteristics of a bonding surface of a semiconductor chip may also be predicted. For example, a type, a curvature value, a position, etc. of distortion on a bonding surface of a BEOL layer or a BSPDN layer may be predicted. Factors that may be used for the prediction may include types of manufacturing operations (e.g., lithography, deposition, etching, etc.), specific methods for the operations (e.g., chemical vapor deposition (CVD), atomic layer deposition (ALD), etc. in case of deposition), time duration of each manufacturing operation, etc. Types or characteristics of a boning surface may also be included in the factors for the prediction. For example, the factors may include whether the bonding surface is that of a BEOL layer, a BSPDN layer, or any other layer in a semiconductor chip, and what type of materials form the boning surface.

Based on the foregoing prediction, a carrier wafer having corresponding patterns and material(s) filled therein that may counter act the predicted distortion may be selected from the pool of carrier wafers, according to embodiments. As described above, the patterns that may be selected include the examples shown in FIGS. 6A to 6D. Further, although some carrier wafers have the same patterns, depths of the pattern may differ in these carrier wafers.

According to an embodiment, the prediction of distortion of a bonding surface and selecting a corresponding carrier wafer may be implemented by an artificial intelligence (AI) processor. The AI processor may control processing of input data according to a predefined operation rule or AI model stored in a nonvolatile memory and a volatile memory connected to the AI processor. The predefined operation rule or AI model may be provided by applying a training or learning algorithm to multiple pieces of learning data. The learning may be executed in a device including the AI processor.

The input data to the AI processor may include the above-described various factors for predicting the distortion of the bonding surface. The AI model may include a plurality of neural network layers each of which may include the various factors by category. For example, the types of semiconductor chip to be manufactured and bonded may be included in a 1^{st} layer, the types of manufacturing operations applied to a plurality of semiconductor chips may be included in a 2^{nd} layer, the specific methods of each manufacturing operation may be included in a 3^{rd} layer, etc. Moreover, each layer has a plurality of weights. Calculation in one layer may be executed by using a result of calculation in a previous layer and a plurality of weights of a current layer. Examples of the neural network may include, but not limited to convolutional neural networks (CNNs), deep neural networks (DNNs), cyclic neural networks (RNNs), restricted Boltzmann machines (RBMs), deep belief networks (DBNs), bidirectional cyclic deep neural networks (BRDNNs), generative confrontation networks (GANs) and deep Q networks.

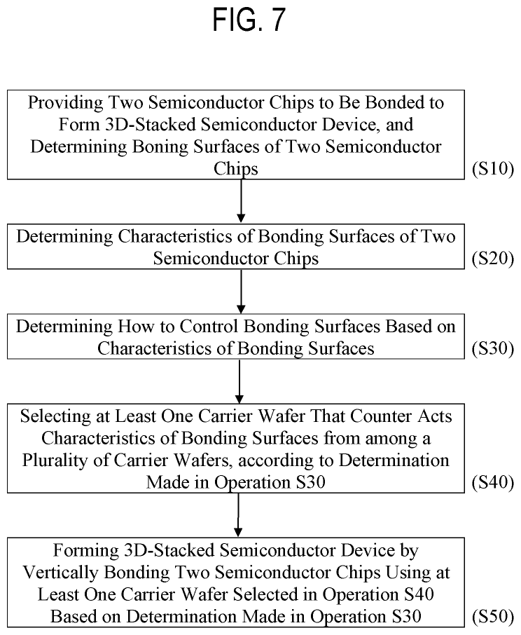

FIG. 7 illustrates a method for manufacturing a 3D-stacked semiconductor device by controlling bending or warpage on a bonding surface of at least one semiconductor chip, according to embodiments.

In operation S10, two semiconductor chips to be bonded to form a 3D-stacked semiconductor device are provided, and boning surfaces of the two semiconductor chips may be determined.

According to embodiments, the bonding surfaces to be bonded to each other in the two semiconductor chips may include a BEOL layer or a BSPDN layer, not being limited thereto.

In operation S20, characteristics of the bonding surfaces of the two semiconductor chips may be determined. The characteristics of the bonding surfaces may include existence of distortion on the bonding surfaces, a type of the distortion, dimensions such as a curvature value, a position, etc. of the distortion on the bonding surfaces, a distorted material in the bonding surfaces, etc., according to embodiments. The characteristics of the bonding surfaces may be determined by, for example, microscopic optical inspection known in the art.

According to embodiments, when the characteristics of the bonding surfaces are not determined, they may be predicted based on an AI processor or AI models described above.

In operation S30, it may be determined how to control the bonding surfaces based on the characteristics of the bonding surfaces.

For example, when two bonding surfaces of the two semiconductor chips are bent convex as shown in FIG. 1A, it may be determined to control the two bonding surfaces to be flat. As another example, as shown in FIG. 4, it may be determined to control the bonding surface of a lower-stack semiconductor chip among the two semiconductor chips to be bent-concave while the bonding surface of an upper-stack semiconductor chip among the two semiconductor chip may maintain the existing bent-convex state.

In operation S40, at least one carrier wafer that counter acts the characteristics of the bonding surfaces may be selected from among a plurality of carrier wafers, according to the determination made in operation S30.

For this operation, a pool of carrier wafers may have been prepared. Each of the carrier wafers may have a plurality of patterns on a bottom surface, and one or more stress materials may be filled therein. The carrier wafer pool may also include a carrier wafer without any pattern on its surface.

In this operation, for example, when two semiconductor chips to be bonded to each other are determined or predicted to have bent-convex bonding surfaces, two carrier wafers having patterns with tensile stress materials may be selected from the carrier wafer pool to control the bent-convex bonding surfaces to be flat. As another example, when a bonding surface of an upper-stack semiconductor chip is determined or predicted to be convex, and a bonding surface of a lower-stack semiconductor chip is determined or predicted to be flat or convex, a carrier wafer having a plain pattern, i.e., no patterns, may be attached to the upper-stack semiconductor chip, and a carrier wafer having patterns filled in with a tensile stress material may be selected to control the bonding surface of the lower-stack semiconductor chip to be bent concave for conformal bonding to the convex boning surface of the upper-stack semiconductor chip.

In operation S50, a 3D-stacked semiconductor device may be formed by vertically bonding the two semiconductor chips using the at least one carrier wafer selected in operation S40 based on the determination made in operation S30.

In this operation, at least one the two semiconductor chips to be bonded to each other may be attached to at least one carrier wafer selected in operation 40, and the two semiconductor chip may be bonded through thermal processing using the selected carrier wafer.

Although not shown in the drawings, it is understood that at least one of the two carrier wafers shown in each of the 3D-stacked semiconductor devices 30, 40 and 50 may be removed when the 3D-stacked semiconductor device is completed. This is because the removed carrier wafer may be simply a dummy wafer used as a supporting structure during the process of bonding the corresponding two semiconductor chips.

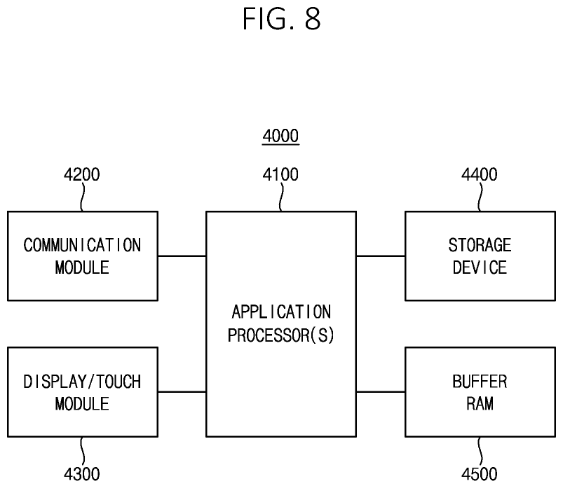

FIG. 8 is a schematic block diagram illustrating an electronic device including a 3D-stacked semiconductor device formed by vertically bonding two semiconductor chips as shown in FIGS. 3 to 5, according to an example embodiment.

Referring to FIG. 8, an electronic device 4000 may include at least one application processor 4100, a communication module 4200, a display/touch module 4300, a storage device 4400, and a buffer random access memory (RAM) 4500. The electronic device 4000 may be a mobile device such as a smartphone or a tablet computer, not being limited thereto, according to embodiments.

The application processor 4100 may control operations of the mobile device 4000. The communication module 4200 is implemented to perform wireless or wire communications with an external device. The display/touch module 4300 is implemented to display data processed by the application processor 4100 and/or to receive data through a touch panel. The storage device 4400 is implemented to store user data. The storage device 4400 may be an embedded multimedia card (eMMC), a solid state drive (SSD), a universal flash storage (UFS) device, etc. The storage device 4400 may perform caching of the mapping data and the user data as described above.

The buffer RAM 4500 may temporarily store data used for processing operations of the mobile device 4000. For example, the buffer RAM 4500 may be volatile memory such as double data rate (DDR) synchronous dynamic random access memory (SDRAM), low power double data rate (LPDDR) SDRAM, graphics double data rate (GDDR) SDRAM, Rambus dynamic random access memory (RDRAM), etc.

Although not shown in FIG. 8, the electronic device 4000 may further include at least one sensor such as a complementary-metal-oxide-semiconductor (CMOS) image sensor.

At least one component in the electronic device 4000 may include at least one of the 3D-stacked semiconductor devices 30 to 50 shown in FIGS. 3 to 5.

The foregoing is illustrative of exemplary embodiments and is not to be construed as limiting the inventive concept. Although a few exemplary embodiments have been described, those skilled in the art will readily appreciate that many modifications are possible in the above embodiments without materially departing from the inventive concept.

What is claimed is:

1. A semiconductor device comprising:
a 1^{st} carrier wafer; and
a 1^{st} semiconductor chip on the 1^{st} carrier wafer,
wherein the 1^{st} carrier wafer comprises at least one 1^{st} pattern, and
wherein the at least one 1^{st} pattern comprises therein a 1^{st} stress material which is different from a material forming the 1st carrier wafer, and configured to expand or shrink by thermal processing.

2. The semiconductor device of claim 1, wherein the 1^{st} semiconductor chip is on a 1^{st} surface of the 1^{st} carrier wafer, and the at least one 1^{st} pattern is formed on a 2^{nd} surface, opposite to the 1^{st} surface, of the 1^{st} carrier wafer.

3. The semiconductor device of claim 1, wherein the 1^{st} stress material is a compressive stress material or a tensile stress material having a thermal expansion coefficient different from the material forming the 1^{st} carrier wafer.

4. The semiconductor device of claim 1, further comprising a 2^{nd} semiconductor chip vertically bonded to the 1^{st} semiconductor chip.

5. The semiconductor device of claim 4, wherein the 2^{nd} semiconductor chip is on a 2^{nd} carrier wafer,
wherein the 2^{nd} carrier wafer comprises at least one 2^{nd} pattern, and
wherein the at least one 2^{nd} pattern comprises therein a 2^{nd} stress material which is different from a material forming the 2nd carrier wafer, and configured to expand or shrink by the thermal processing.

6. The semiconductor device of claim 5, wherein the 2^{nd} semiconductor chip is on a 1^{st} surface of the 2^{nd} carrier wafer, and the at least one 2^{nd} pattern is formed on a 2^{nd} surface, opposite to the 1^{st} surface, of the 2^{nd} carrier wafer.

7. The semiconductor device of claim 5, wherein the 1^{st} stress material is a compressive stress material or a tensile stress material having a thermal expansion coefficient different from the material forming the 1^{st} carrier wafer, and
wherein the 2^{nd} stress material is the compressive stress material or the tensile stress material having a thermal expansion coefficient different from the material forming the 2^{nd} carrier wafer.

8. The semiconductor device of claim 5, wherein the at least one 1^{st} pattern comprises a plurality of 1^{st} patterns, and the at least one 2^{nd} pattern comprise a plurality of 2^{nd} patterns, and
wherein the plurality of 1^{st} patterns are different from the plurality of 2^{nd} patterns.

9. The semiconductor device of claim 8, wherein the 1^{st} stress material is different from the 2^{nd} stress material.

10. The semiconductor device of claim 5, wherein a bonding surface of the 1^{st} semiconductor chip comprises a surface of a back-end-of-line (BEOL) layer of the 1^{st} semiconductor chip, and
wherein a bonding surface of the 2^{nd} semiconductor chip bonded to the bonding surface of the 1^{st} semiconductor chip comprises a surface of a BEOL layer of the 2^{nd} semiconductor chip.

11. The semiconductor device of claim 10, wherein the at least one 1^{st} pattern is different from the at least one 2^{nd} pattern, and the 1^{st} stress material is different from the 2^{nd} stress material.

12. The semiconductor device of claim 5, wherein a bonding surface of the 1^{st} semiconductor chip comprises a surface of a back side power delivery network (BSPDN) layer, comprising a metal line and an interlayer dielectric (ILD) structure, of the 1^{st} semiconductor chip, and
wherein a bonding surface of the 2^{nd} semiconductor chip bonded to the bonding surface of the 1^{st} semiconductor chip comprises a surface of a BSPDN layer, comprising a metal line and an ILD structure, of the 2^{nd} semiconductor chip.

13. The semiconductor device of claim 12, wherein the at least one 1^{st} pattern is different from the at least one 2^{nd} pattern, and the 1^{st} stress material is different from the 2^{nd} stress material.

14. A carrier wafer comprising:
a 1^{st} surface on which an integrated circuit is to be attached; and
a 2^{nd} surface opposite to the 1^{st} surface,
wherein at least one pattern is formed on the 2nd surface, and a stress material is included in the at least one pattern, and
wherein the stress material is different from a material forming the carrier wafer, and configured to expand or shrink subject to thermal processing.

15. The carrier wafer of claim 14, wherein the stress material is a compressive stress material or a tensile stress material having a thermal expansion coefficient different from the material forming the carrier wafer.

16. A method of manufacturing a semiconductor device, the method comprising:
providing a 1^{st} semiconductor chip and a 2^{nd} semiconductor chip;
determining characteristics of a 1^{st} bonding surface of the 1^{st} semiconductor chip and a 2^{nd} bonding surface of the 2^{nd} semiconductor chip to be bonded to the 1^{st} bonding surface;
forming the 1^{st} semiconductor chip on a 1^{st} carrier wafer, and forming a 2^{nd} semiconductor chip on a 2^{nd} carrier wafer; and
vertically bonding the 1^{st} semiconductor chip and the 2^{nd} semiconductor chip to each other through a thermal process,
wherein at least one of the 1^{st} carrier wafer and the 2^{nd} carrier wafer comprises a plurality patterns and a stress material therein which is different from a material forming the 1^{st} carrier wafer or the 2^{nd} carrier wafer, and configured to expand or shrink by the thermal process.

17. The method of claim 16, wherein the 1^{st} carrier wafer comprises at least one 1^{st} pattern and a 1^{st} stress material formed therein which is different from the material forming the 1^{st} carrier wafer, and configured to expand or shrink subject to the thermal processing, and wherein the 2^{nd} carrier wafer comprises at least one 2^{nd} pattern and a 2^{nd} stress material formed therein which is different from the material forming the 2^{nd} carrier wafer, and configured to expand or shrink subject to the thermal processing.

18. The method of claim 16, wherein the vertically bonding comprises controlling at least one of the 1st bonding surface or the 2^{nd} bonding surface to be flat.

19. The method of claim 16, wherein the 1^{st} carrier wafer comprises the patterns and the stress material therein, and the 2^{nd} carrier wafer does not comprise the patterns and the stress material therein, and
wherein the vertically bonding comprises controlling the 1^{st} bonding surface to correspond to the 2^{nd} bonding surface.

20. The method of claim 16, wherein the stress material is a compressive stress material or a tensile stress material having a thermal expansion coefficient different from the material forming the 1^{st} carrier wafer or the 2^{nd} carrier wafer.

21. The method of claim 16, wherein the characteristics of the 1^{st} bonding surface and the 2^{nd} bonding surface are determined by prediction using a machine learning algorithm,
wherein the machine learning algorithm is implemented by an artificial intelligence model comprising a plurality neural network layers, and
wherein each of the neural network layers comprises at least one factor used for the prediction of the characteristics of the 1^{st} bonding surface and the 2^{nd} bonding surface.

22. The method of claim 21, wherein the machine learning algorithm comprises pairing the 1^{st} bonding surface and the 2^{nd} bonding surface with the 1^{st} carrier wafer and the 2^{nd} carrier wafer, respectively, from among a plurality carrier wafers.
